(19) United States
(12) Patent Application Publication
(10) Pub. No.: US 2024/0170926 A1
(43) Pub. Date: May 23, 2024

(54) LIGHT SOURCE DEVICE

(71) Applicant: NICHIA CORPORATION, Anan-shi (JP)

(72) Inventor: Tomokazu TAJI, Anan-shi (JP)

(21) Appl. No.: 18/515,253

(22) Filed: Nov. 20, 2023

(30) Foreign Application Priority Data
Nov. 22, 2022 (JP) 2022-186764

(51) Int. Cl. H01S 5/42; H01S 5/02255; H01S 5/14

(52) U.S. Cl. CPC H01S 5/42; H01S 5/02255; H01S 5/141

(57) ABSTRACT

A light source device includes a base portion, first semiconductor laser elements, one or more first power supply terminals, first reflecting members, one or more second semiconductor laser elements, one or more second power supply terminals, and one or more second reflecting members. The one or more first power supply terminals are each disposed respectively in a region interposed between adjacent ones of the first semiconductor laser elements in an array direction. The one or more second semiconductor laser elements are each configured to emit laser light in a second optical axis direction opposite to a first optical axis direction of the first semiconductor laser elements. At least one of the one or more second reflecting members is disposed in a region interposed between adjacent ones of the first reflecting members in the array direction.

### CROSS-REFERENCE TO RELATED APPLICATION

The present application claims priority to Japanese Patent Application No. 2022-186764, filed on Nov. 22, 2022, the disclosure of which is hereby incorporated herein by reference in its entirety.

### TECHNICAL FIELD

The present disclosure relates to a light source device.

### BACKGROUND ART

In recent years, various light source devices that include a plurality of semiconductor lasers or the like as excitation light sources, perform (using phosphors or the like) wavelength conversion on light emitted from the excitation light sources, and extract light have been proposed (for example, JP 2019-161062 A).

### SUMMARY

In such a light source device, for an operation with less electric power, an innovation for lowering a driving voltage is required.

A light source device disclosed in the present application includes a base portion, a plurality of first semiconductor laser elements, one or more first power supply terminals, a plurality of first reflecting members, one or more second semiconductor laser elements, one or more second power supply terminals, and one or more second reflecting members. The first semiconductor laser elements are arrayed on the base portion along an array direction. Each of the first semiconductor laser elements is configured to emit laser light in a first optical axis direction perpendicular to the array direction. The one or more first power supply terminals are each disposed respectively in a region interposed between adjacent ones of the first semiconductor laser elements and electrically connected to a corresponding one of the first semiconductor laser elements. The first reflecting members are arrayed on the base portion along the array direction. The first reflecting members are spaced apart from the first semiconductor laser elements in the first optical axis direction. The one or more second semiconductor laser elements are each configured to emit laser light in a second optical axis direction perpendicular to the array direction and opposite to the first optical axis direction. The one or more second power supply terminals are each electrically connected to a corresponding one of the one or more second semiconductor laser elements. The one or more second reflecting members are spaced apart from the one or more second semiconductor laser elements in the second optical axis direction. At least one of the one or more second reflecting members is disposed in a region interposed between adjacent ones of the first reflecting members in the array direction.

According to the embodiment of the present disclosure, the light source device that allows reduction in thermal interference between semiconductor lasers during driving of the semiconductor lasers and allows reduction in a driving voltage by shortening of a wire length can be provided.

### BRIEF DESCRIPTION OF DRAWINGS

FIG. 1A is a schematic top view of a light source device according to one embodiment of the present application.

FIG. 1B is a schematic perspective view of the light source device in FIG. 1A illustrating a sealed state.

FIG. 1C is a schematic end view taken along a line IC-IC of the light source device in FIG. 1B.

FIG. 1D is a partially enlarged schematic plan view for explaining a positional relationship between members in the light source device of FIG. 1A.

FIG. 1E is a partially enlarged schematic plan view for explaining another positional relationship between members in the light source device of FIG. 1A.

FIG. 2 is a schematic top view of a light source device according to another embodiment of the present application.

### DESCRIPTION OF EMBODIMENTS

Embodiments of the present invention are described below with reference to the drawings. The following embodiments are for embodying the technical concept of the present invention, and are not intended to limit the present invention. Note that the sizes, positional relationship, or the like of members illustrated in each of the drawings may be exaggerated for clarity of description. In each of the drawings, a three-dimensional orthogonal coordinate system with XYZ may be used to indicate a specific direction or position. In this case, a direction in which first semiconductor laser elements are arrayed in an XY flat plane may be referred to as an X direction, and a direction orthogonal to the XY flat plane may be referred to as a Z direction or a vertical direction. The X direction, a Y direction, or the Z direction means not only one specific direction but also both directions including a direction opposite to the specific direction. However, each of a first optical axis direction of the first semiconductor laser element and a second optical axis direction of a second semiconductor laser element indicates a corresponding one of the Y directions, for example, Y1 and Y2 directions. As a cross-sectional view, an end view illustrating only a cut surface may be illustrated. In the present specification or the claims, a shape of a polygon, such as a trapezoid, a triangle, and a quadrangle, is not limited to a polygon in a mathematically strict sense and also includes a shape in which a corner of the polygon is processed to be rounded, chamfered, beveled, coved, or the like. Furthermore, a shape obtained by processing not only the corner (an end of a side) of the polygon but also a middle portion of the side is similarly referred to as a polygon. In other words, a shape partially processed while leaving the polygon as a base is included in the “polygon” described in the present specification and the claims. The same applies to not only the polygon but also a circle, an uneven shape, and the like. When a specific member is described, a first member and a second member may be collectively described as a “member.”

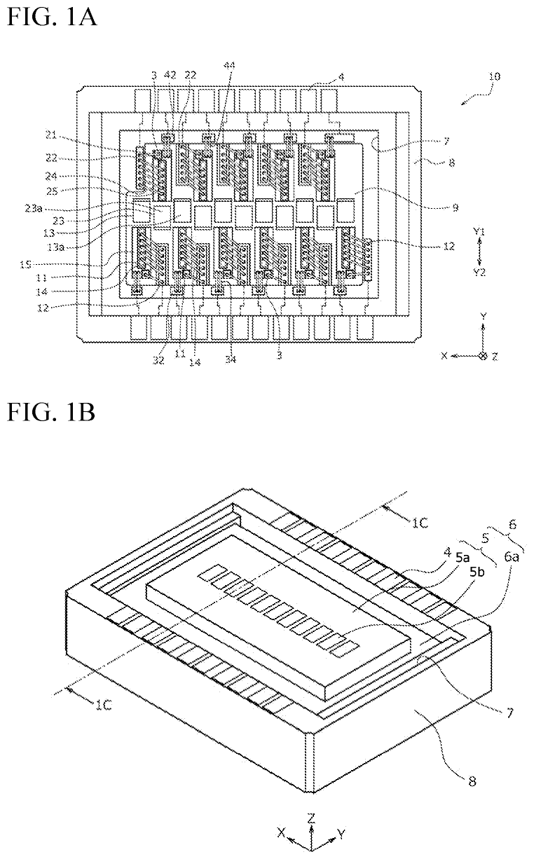

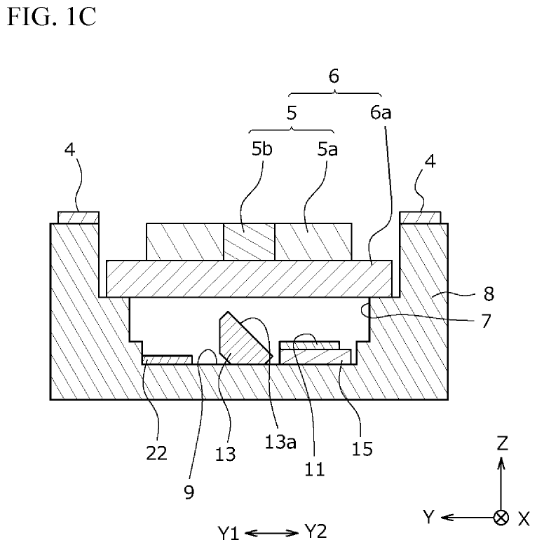

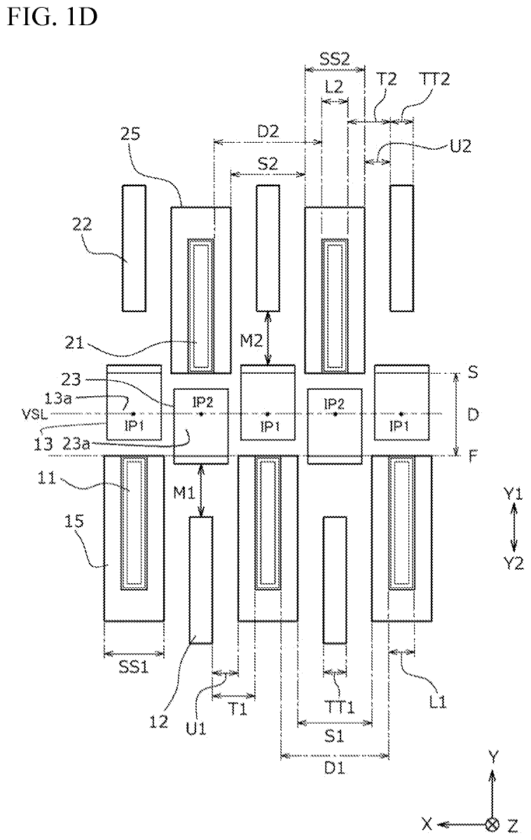

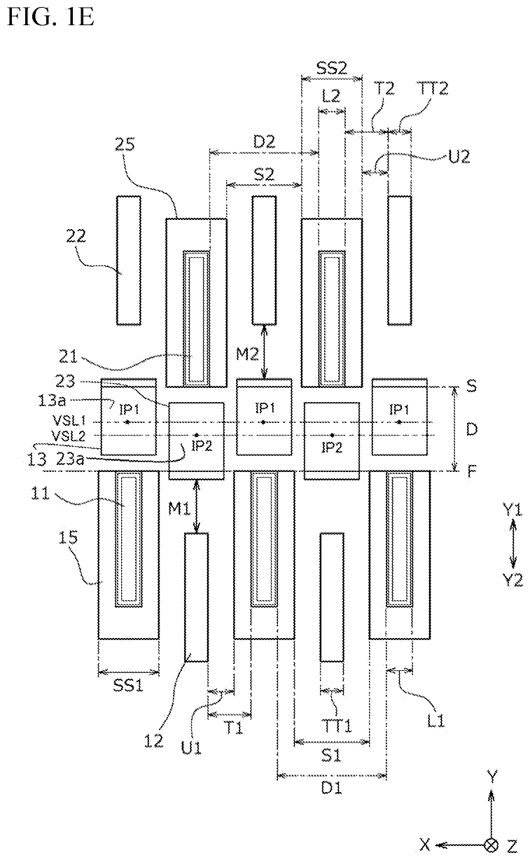

For example, as illustrated in FIG. 1A, a light source device 10 according to one embodiment of the present application includes a base portion 9, a plurality of first semiconductor laser elements 11, one or more first power supply terminals 12, a plurality of first reflecting members 13, one or more second semiconductor laser elements 21, one or more second power supply terminals 22, and one or more second reflecting members 23.

The plurality of first semiconductor laser elements 11 are arrayed on the base portion 9 along an array direction (for example, the X direction), and each of the first semiconductor laser elements 11 emits laser light in the first optical axis direction (for example, the Y1 direction) orthogonal to the array direction.

Each of one or more first power supply terminals 12 is disposed in a region interposed between the two adjacent first semiconductor laser elements 11 among the plurality of first semiconductor laser elements 11 and is electrically connected to a corresponding one of the first semiconductor laser elements 11. However, with respect to the first semiconductor laser element 11 disposed at one end of the plurality of arrayed first semiconductor laser elements 11, the first power supply terminal 12 does not have to be disposed in a region interposed between the two adjacent first semiconductor laser elements 11 but is disposed lateral to the first semiconductor laser element 11 at one end.

The plurality of first reflecting members 13 are arrayed on the base portion 9 along the array direction, and are spaced apart from the plurality of first semiconductor laser elements 11 in the first optical axis direction Y1.

One or more second semiconductor laser elements 21 are disposed so as to emit laser light in the second optical axis direction (for example, the Y2 direction) as a direction orthogonal to the array direction and opposite to the first optical axis direction Y1.

One or more second power supply terminals 22 are electrically connected to one or more second semiconductor laser elements 21.

One or more second reflecting members 23 are spaced apart from one or more second semiconductor laser elements 21 in the second optical axis direction Y2.

At least one second reflecting member 23 is disposed in a region interposed between the two first reflecting members 13 adjacent in the array direction among the plurality of first reflecting members 13.

By arraying the first semiconductor laser elements 11 and the first reflecting members 13, and the second semiconductor laser elements 21 and the second reflecting members 23 on the base portion 9 so as to be alternately arranged in the array direction, a predetermined space can be provided between the adjacent first semiconductor laser elements 11. By disposing the first power supply terminal 12 in this predetermined space, the distance between the first semiconductor laser element 11 and the first power supply terminal 12 can be reduced, and therefore a length of first conductive members 14 connecting the first power supply terminal 12 and the first semiconductor laser element 11 can be reduced. As a result, a driving voltage can be reduced. In addition, disposing the first power supply terminal 12 and the second power supply terminal 22 in such predetermined spaces eliminates the need for separately providing a space for disposing the power supply terminals, and thus the device can be downsized.

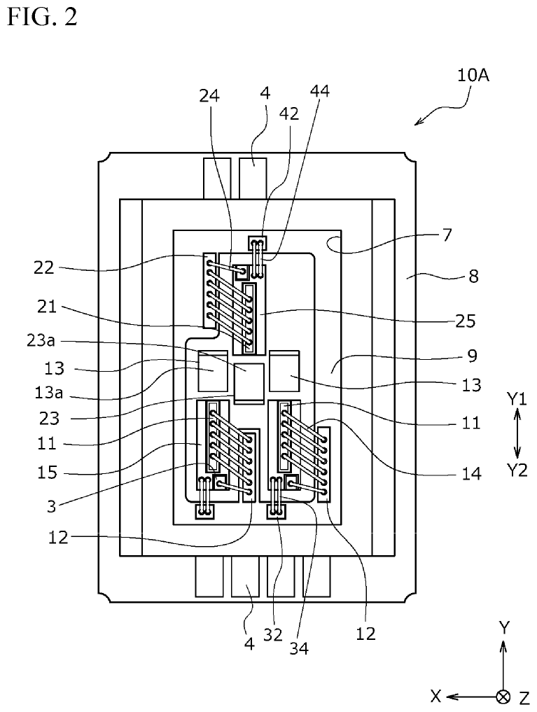

In other words, as illustrated in FIG. 1A, on the base portion 9 of the light source device 10, a plurality of first rows in each of which one of the first semiconductor laser elements 11, one of the first reflecting members 13, and one of the second power supply terminals 22 are disposed in this order in the direction (for example, the Y direction, particularly the Y1 direction) orthogonal to the array direction of the first semiconductor laser elements 11 (that is, the X direction) are present, and a plurality of second rows in each which one of the first power supply terminals 12, one of the second reflecting members 23, and one of the second semiconductor laser elements 21 are disposed in this order in the Y1 direction are present. The first rows and the second rows are alternately disposed along the array direction. As illustrated in FIG. 2, on the base portion 9 of a light source device 10A, one first row in which the first semiconductor laser element 11, the first reflecting member 13, and the second power supply terminal 22 are disposed in this order in the Y1 direction is present, and one second row in which the first power supply terminal 12, the second reflecting member 23, and the second semiconductor laser element 21 are disposed in this order in the Y1 direction is present. The second row may be disposed adjacent to the first row.

### Base Portion 9

The base portion 9 is a member where the semiconductor laser elements, an optical member, and the power supply terminals are disposed.

The base portion 9 can be formed using a ceramic as a main material or made of a ceramic. Examples of the ceramic include aluminum nitride, silicon nitride, aluminum oxide, and silicon carbide. Since a ceramic has a small linear expansion coefficient, when the base portion 9 is made of a ceramic, an influence of expansion and/or contraction due to heat can be reduced. As a result, displacement of the optical member or the like can be suppressed. The base portion 9 may partially include a metal, an inorganic substance, or a composite thereof. Examples of the metal, the inorganic substance, and the composite thereof include gold, silver, tungsten, nickel, copper, aluminum, iron, diamond, copper molybdenum, a copper-diamond composite material, and copper tungsten.

A metal portion or the like may be provided on the surface or inside of the base portion 9, as a wiring or the like for electrical connection. As a material of the metal portion, gold, aluminum, silver, copper, tungsten, titanium, platinum, nickel, iron, tin, or the like, or an alloy thereof can be used.

The shape of the base portion 9 may be any of a polygon such as a triangle or a quadrangle, a circle, an ellipse, and the like in a plan view. Among these, a rectangle is preferable. In a case in which the flat plane shape of the base portion 9 is a rectangle, the lengths of the base portion 9 (in the X direction and the Y direction in a plan view) are, for example, in a range from 1.0 mm to 10.0 mm, and are preferably in a range from 2.0 mm to 6.0 mm. The thickness of the base portion 9, that is, the length of the base portion 9 in the Z direction can be appropriately set such that strength enough to support the semiconductor laser elements and the like disposed on the base portion 9 can be ensured. The base portion 9 preferably has a flat plate shape, and the surface thereof on which the semiconductor laser elements and the like are disposed is preferably a flat surface.

First Semiconductor Laser Element 11 and Second Semiconductor Laser Element 21

Although an edge emitting semiconductor laser element or a surface emitting semiconductor laser element can be used as a semiconductor laser element, edge emitting semiconductor laser elements are preferably used as the first semiconductor laser element 11 and the second semiconductor laser element 21. The light emitted from an edge emitting semiconductor laser element forms a far field pattern (hereinafter referred to as “FFP” in some cases) having an elliptical shape on a surface parallel to the exit end surface of the light. The light passing through the center of the FFP having the elliptical shape, that is, the light having the peak intensity in the light intensity distribution of FFP is referred to as the optical axis of the semiconductor laser element. In the surface emitting semiconductor laser element, the light having the peak intensity in the light intensity distribution of the light emitted from the light exit surface is the optical axis of the semiconductor laser element.

The plurality of first semiconductor laser element 11 are arrayed on the base portion 9. This array direction is referred to as the X direction as described above. In the plurality of first semiconductor laser elements 11, one of the Y directions (Y1 direction), which is the direction orthogonal to the X direction as the array direction, matches the first optical axis direction in which each of the first semiconductor laser elements 11 emits laser light. That is, the plurality of first semiconductor laser elements 11 are arrayed in the X direction, and each of the first semiconductor laser elements 11 is disposed so as to emit laser light in the Y1 direction.

The second semiconductor laser elements 21 are arrayed on the base portion 9. In this case, as illustrated in FIG. 2, the number of the second semiconductor laser elements 21 may be one. As illustrated in FIG. 1A, the plurality of second semiconductor laser elements 21 may be disposed in the X direction. In the second semiconductor laser element 21, one of the Y directions (Y2 direction) matches the second optical axis direction in which the second semiconductor laser element 21 emits laser light. That is, the second semiconductor laser element 21 is disposed so as to emit the laser light in the second optical axis direction, which is the Y2 direction. Further, the two or more second semiconductor laser elements 21 are arrayed in the X direction and each disposed so as to emit the laser light in the Y2 direction.

The first optical axis direction (Y1) and the second optical axis direction (Y2) are preferably parallel to each other and in the opposite directions to each other.

When the three or more first semiconductor laser elements 11 are arrayed, some or all of the first semiconductor laser elements 11 adjacent in the X direction may be disposed at various intervals, but as illustrated in FIG. 1A, all of them are preferably disposed at the same interval. For example, as illustrated in FIG. 1D, an interval D1 between the first semiconductor laser elements 11 adjacent in the X direction is in a range from 1.4 mm to 1.7 mm. The interval D1 of 1.4 mm or more allows reduction in thermal interference between the first semiconductor laser elements 11 adjacent to each other. In addition, the interval D1 of 1.7 mm or less allows reduction in the wiring line length and suppression of the increase in driving voltage.

When the two or more second semiconductor laser elements 21 are arrayed, some or all of the second semiconductor laser elements 21 adjacent in the X direction may be disposed at various intervals, but as illustrated in FIG. 1A, all of them are preferably disposed at the same interval. For example, as illustrated in FIG. 1D, an interval D2 between the second semiconductor laser elements 21 adjacent to each other in the X direction is in a range from 1.4 mm to 1.7 mm. The interval D2 of 1.4 mm or more allows reduction in thermal interference between the second semiconductor laser elements 21 adjacent to each other. In addition, the interval D2 of 1.7 mm or less allows reduction in the wiring line length and suppression of the increase in driving voltage. When the semiconductor laser elements are directly arrayed on the base portion, the interval D1 between the adjacent first semiconductor laser elements 11 and the interval D2 between the adjacent second semiconductor laser elements 21 are larger than widths L1 and L2 of the semiconductor laser elements, respectively, and are 150% or less, preferably 130% or less, more preferably 120% or less of the widths L1 and L2 of the semiconductor laser elements, respectively. The widths L1 and L2 of the semiconductor laser elements are in a range from 0.10 mm to 0.50 mm. When the semiconductor laser elements are disposed on submounts and arrayed on the base portion as described later, the interval between the adjacent first semiconductor laser elements and the interval between the adjacent second semiconductor laser elements are larger than the widths of the submounts, and are 150% or less, preferably 130% or less, more preferably 120% or less of the widths of the submounts. Widths SS1 and SS2 of the submounts are in a range from 0.70 mm to 0.90 mm.

The plurality of first semiconductor laser elements 11 arrayed in the X direction are preferably disposed such that the respective optical axes of light emitted from the plurality of first semiconductor laser elements 11 are parallel to each other. The respective exit surfaces of the plurality of first semiconductor laser elements 11 arrayed in the X direction may be disposed at random positions in the Y direction, but as illustrated in FIG. 1D, are preferably disposed so as to be arrayed on a straight line (for example, on a straight line F) in the X direction.

When the plurality of second semiconductor laser elements 21 are arrayed, the plurality of second semiconductor laser elements 21 arrayed in the X direction are preferably disposed such that the respective optical axes of light emitted from the second semiconductor laser elements 21 are parallel to each other. The respective exit surfaces of the plurality of second semiconductor laser elements 21 arrayed in the X direction may be disposed at random positions in the Y direction, but as illustrated in FIG. 1D, are preferably disposed so as to be arrayed on a straight line (for example, on a straight line S) in the X direction.

The respective exit surfaces of the plurality of first semiconductor laser elements 11 arrayed on the straight line F and the respective exit surfaces of the plurality of second semiconductor laser elements 21 arrayed on the straight line S are preferably parallel to the X direction. In this case, an interval D between the straight lines F and S, for example, is in a range from 0.80 mm to 1.20 mm, and preferably in a range from 0.95 mm to 1.0 mm. These straight lines F and S may overlap.

The plurality of first semiconductor laser elements 11 arrayed in the X direction and one or more second semiconductor laser elements 21 arrayed in the X direction are preferably disposed so as not to overlap with each other in the X direction. “Not overlapping with each other” means that the first semiconductor laser element 11 and the second semiconductor laser element 21 do not coexist in the entire cross section taken along the YZ flat plane. Also, the first semiconductor laser element 11 and the second semiconductor laser element 21 preferably do not coexist in the entire cross section taken along the XZ flat plane. With such an array, even when the first semiconductor laser elements 11, the first semiconductor laser element 11 and the second semiconductor laser element 21, and the second semiconductor laser elements 21 are arrayed close to each other, a predetermined distance is provided between the semiconductor laser elements, and the first power supply terminal 12 and the second power supply terminal 22 can be disposed in the spaces between the semiconductor laser elements. Therefore, the wiring line length can be reduced and the increase in driving voltage can be suppressed.

For the first semiconductor laser element 11 and the second semiconductor laser element 21, for example, a semiconductor laser element that exhibits a wavelength peak in blue, a semiconductor laser element that exhibits a wavelength peak in green, a semiconductor laser element that exhibits a wavelength peak in red, or a semiconductor laser element that exhibits a wavelength peak in a color other than these can be employed. A wavelength peak in blue refers to light within a range from 420 nm to 494 nm, a wavelength peak in green refers to light within a range from 495 nm to 570 nm, and a wavelength peak in red refers to light within a range from 605 nm to 750 nm. Examples of the semiconductor laser element that exhibits the wavelength peak in blue and the semiconductor laser element that exhibits the wavelength peak in green include a semiconductor laser element including a nitride semiconductor. As the nitride semiconductor, for example, a semiconductor layer of GaN, InGaN, AlGaN, or the like can be used. Examples of the semiconductor laser element that exhibits the wavelength peak in red include a semiconductor laser element including an InAlGaP-based, GaInP-based, GaAs-based, or AlGaAs-based semiconductor layer.

Some or all of the plurality of first semiconductor laser elements and one or more second semiconductor laser elements may have the same or different wavelength peaks, and in particular, all of the plurality of first semiconductor laser elements and one or more second semiconductor laser elements preferably exhibit the wavelength peaks in blue. When all of the semiconductor laser elements exhibit the wavelength peaks in blue in this manner, the effect of reducing the thermal interference as described above can be more advantageously utilized, and the effect of reducing the driving voltage can be more advantageously utilized.

The semiconductor laser element may be any of a single emitter having one emitter, a multi-emitter having two or more emitters, and the like. When the semiconductor laser element includes a plurality of emitters, laser light that forms an elliptical FFP is emitted from the exit end surface of each of the emitters.

The first semiconductor laser element 11 and the second semiconductor laser element 21 may be disposed on the base portion 9 with bond members or the like therebetween, or may be disposed on the base portion 9 with the submounts or the like therebetween. In particular, the first semiconductor laser elements 11 and the second semiconductor laser elements 21 are preferably disposed on the submounts. With such a configuration, it can be inhibited that the base portion 9 is exposed to the light emitted from the semiconductor laser element and stray light is generated.

Bond Member

As described above, the bond member can be used when the semiconductor laser element is disposed on the base portion 9 or when the semiconductor laser element is disposed on the submount described later. Examples of the bond member include solders such as tin-bismuth based solders, tin-copper based solders, tin-silver based solders, and gold-tin based solders, eutectic alloys such as alloys containing Au and Sn as main components, alloys containing Au and Si as main components, and alloys containing Au and Ge as main components, conductive pastes made from silver, gold, palladium, or the like, anisotropic conductive materials such as ACP and ACF, waxes made from low-melting-point metals, conductive adhesives of combination of these, and conductive composite adhesives.

Submount

To dispose the semiconductor laser elements on the base portion 9, it is preferable that the semiconductor laser elements are disposed on the submounts and the submounts on which the semiconductor laser elements are disposed are disposed on the base portion. That is, a plurality of first submounts 15 are disposed in the array direction on the base portion 9, and the first semiconductor laser elements 11 are disposed on the corresponding first submounts 15. In addition, one second submount 25 is disposed or a plurality of second submounts 25 are disposed in the array direction on the base portion 9, and the second semiconductor laser elements 21 are disposed on the corresponding second submounts 25. It is preferable that the submount has two bonding surfaces and the two bonding surfaces have shapes of a column or a polygonal column such as a quadrangular column that are parallel to each other. In particular, a rectangular parallelepiped is preferable.

The submount can be formed using, for example, a ceramic such as silicon nitride, aluminum nitride, aluminum oxide, or silicon carbide, a metal such as gold, silver, copper, tungsten, or nickel, or diamond. In particular, the submount is preferably formed using a material having a good heat dissipation property. A metal film for bonding is preferably provided on each of the bonding surfaces. The semiconductor laser element is preferably fixed to one bonding surface of the submount.

The widths SS1 and SS2 (the lengths in the X direction) of the submounts are larger than the widths L1 and L2 of the semiconductor laser elements, respectively, and are, for example, in a range from 200% to 500% or from 200% to 400% of the widths L1 and L2 of the semiconductor laser elements, respectively. In addition, for example, the widths SS1 and SS2 of the submounts are in a range from 0.70 mm to 0.90 mm.

A width S1 between the first submounts 15 is preferably in a range from 0.90 mm to 1.20 mm. When a plurality of second submounts 25 are disposed, a width S2 between them is preferably in a range from 0.90 mm to 1.20 mm.

In addition, the widths SS1 and SS2 of the submounts are larger than widths TT1 and TT2 of the power supply terminals described later, respectively, and are, for example, in a range from 200% to 500% or from 200% to 400% of the widths TT1 and TT2 of the power supply terminals, respectively. The thicknesses can be appropriately set according to the performance of the semiconductor laser elements.

The width SS1 of the submount on which the first semiconductor laser element 11 is disposed is equal to or greater than a width of the first reflecting member 13 (the length in the X direction) described later. By thus ensuring the area of the bonding surface of the first submount 15, the heat dissipation property can be improved.

First Power Supply Terminal 12 and Second Power Supply Terminal 22

The first power supply terminal 12 and the second power supply terminal 22 are members that are electrically connected to the first semiconductor laser element 11 and the second semiconductor laser element 21, respectively, to apply driving voltages to the semiconductor laser elements. The plurality of first power supply terminals 12 are disposed for the respective first semiconductor laser elements 11. One or more second power supply terminals 22 are disposed for the respective second semiconductor laser elements 21.

The first power supply terminal 12 and the second power supply terminal 22 are electrically connected to external connection electrodes 4 via a conductive circuit embedded in a wall portion 8 or/and the base portion 9. The first power supply terminal 12 and the second power supply terminal 22 extend from the wall portion 8 toward the first reflecting member 13 or the second reflecting member 23 in a top view. In FIG. 1A, the first power supply terminal 12 and the second power supply terminal 22 have rectangular shapes in contact with the inner lateral surface of the wall portion 8. The widths TT1 and TT2 of the first power supply terminal 12 and the second power supply terminal 22 (the lengths in the X direction) are, for example, in a range from 0.25 mm to 0.35 mm. The lengths of the first power supply terminal 12 and the second power supply terminal 22 in the Y direction are, for example, in a range from 1.40 mm to 1.60 mm.

The dimensions of the first power supply terminal 12 and the second power supply terminal 22 may be appropriately set according to the installation positions. In FIG. 1A, the first power supply terminal 12 that is not interposed between the plurality of first semiconductor laser elements 11 and the second power supply terminal 22 that is not interposed between the plurality of second semiconductor laser elements 21 have dimensions different from those of the other power supply terminals, and have a length in the X direction of 0.65 mm and a length in the Y direction of 0.90 mm.

The first power supply terminal 12 is disposed in a region interposed between the two adjacent first semiconductor laser elements 11 among the plurality of first semiconductor laser elements 11 so as to be electrically connected to a corresponding one of the first semiconductor laser elements 11. However, as illustrated in FIG. 1A, with respect to the first semiconductor laser element 11 disposed at one end of the plurality of arrayed first semiconductor laser elements 11, the first power supply terminal 12 does not have to be disposed in a region interposed between the two adjacent first semiconductor laser elements 11 but is disposed lateral to the first semiconductor laser element 11 at one end. The first power supply terminal 12 is present on the opposite side of the second semiconductor laser element 21 with respect to the second reflecting member 23 described later. As illustrated in FIG. 1D, a distance M1 (that is, the interval in the Y direction) between the first power supply terminal 12 and the second reflecting member 23 is shorter than the length of the first power supply terminal 12 in the first optical axis direction Y1. The distance M1 between the first power supply terminal 12 and the second reflecting member 23 is, for example, less than 100% of the length of the first power supply terminal 12 in the first optical axis direction Y1, and is preferably 90% or less, more preferably 80% or less. Moreover, the distance M1 is, for example, 20% or more of the length of the first power supply terminal 12 in the first optical axis direction Y1, and is more preferably 30% or more thereof. With such a configuration, the length of the first conductive member 14 described later can be shortened, and the driving voltage can be reduced.

The second power supply terminal 22 is a region disposed to be electrically connected to the second semiconductor laser element 21, and when only one second semiconductor laser element 21 is disposed, as illustrated in FIG. 2, one second power supply terminal 22 is disposed lateral to the second semiconductor laser element 21 in the same manner as being disposed lateral to the first semiconductor laser element 11 at one end described above. In this case, the second power supply terminal 22 may be disposed on either side of the second semiconductor laser element 21. When the plurality of second semiconductor laser elements 21 are disposed, as illustrated in FIG. 1A, the second power supply terminal 22 is disposed in the region interposed between the two adjacent second semiconductor laser elements 21. However, with respect to the second semiconductor laser element 21 disposed at one end of the plurality of arrayed second semiconductor laser elements 21, the second power supply terminal 22 does not have to be disposed in a region interposed between the two adjacent second semiconductor laser elements but is disposed lateral to the second semiconductor laser element 21 at one end. The second power supply terminal 22 is present on the opposite side of the first semiconductor laser element 11 with respect to the first reflecting member 13 described later. As illustrated in FIG. 1D, a distance M2 (that is, the interval in the Y direction) between the second power supply terminal 22 and the first reflecting member 13 is shorter than the length of the second power supply terminal 22 in the second optical axis direction Y2. The distance M2 between the second power supply terminal 22 and the first reflecting member 13 is, for example, less than 100% of the length of the second power supply terminal 22 in the second optical axis direction Y2, and is preferably 90% or less, more preferably 80% or less, and preferably 20% or more, more preferably 30% or more thereof. With such a configuration, the length of a second conductive member 24 described later can be shortened, and the driving voltage can be reduced.

In a case in which each of the first power supply terminal 12 and the second power supply terminal 22 are disposed between the semiconductor laser elements, as illustrated in FIG. 1D, intervals T1 between the first semiconductor laser element 11 and the first power supply terminal 12 in the X direction and intervals T2 between the second semiconductor laser element 21 and the second power supply terminal 22 in the X direction may be partially or entirely different, but are preferably entirely the same. As a result, the lengths of conductive members described later connected to the respective semiconductor laser elements can be made uniform, and thus driving powers of the respective semiconductor laser elements can be made uniform. When the semiconductor laser elements are mounted on the submounts, intervals U1 between the first submount 15 and the first power supply terminal 12 in the X direction and intervals U2 between the second submount 25 and the second power supply terminal 22 in the X direction may be partially or entirely different, but are preferably entirely the same.

The end portions of the first power supply terminal 12 and the second power supply terminal 22 may be disposed so as to be located at distances from the wall portion 8 equivalent to those of the end portions of the first semiconductor laser element 11 and the second semiconductor laser element 21 closer to the inner lateral surface of the wall portion 8, respectively. The end portions of the first power supply terminals 12 and the second power supply terminals 22 closer to the inner lateral surface of the wall portion 8 may be disposed so as to be located closer to the inner lateral surface of the wall portion 8 than the end portions of the first semiconductor laser elements 11 and the second semiconductor laser elements 21 closer to the inner lateral surface of the wall portion 8, respectively. In particular, the end portions of the first power supply terminals 12 and the second power supply terminals 22 closer to the inner lateral surface of the wall portion 8 are preferably disposed at positions closer to the inner lateral surface of the wall portion 8 than the first semiconductor laser elements 11 and the second semiconductor laser elements 21 are, respectively. With such a configuration, contact between the first conductive member 14 and the second conductive member 24, and the first reflecting member 13 and the second reflecting member 23 can be prevented. Flat plane shapes, sizes, thicknesses, and the like of the first power supply terminal 12 and the second power supply terminal 22 can be appropriately set according to the performance and the like of the semiconductor laser elements to which voltages are applied, and the flat plane shapes and the sizes with which the first power supply terminal 12 and the second power supply terminal 22 fit within regions interposed between the first semiconductor laser elements 11 and/or regions interposed between the second semiconductor laser elements 21 or regions lateral thereto are preferred. Examples include the flat plane shape and the size equivalent to, larger than, or smaller than those of the semiconductor laser elements.

The widths TT1 and TT2 of the first power supply terminal 12 and the second power supply terminal 22 can be appropriately set according to a voltage to be used or the like. For example, the widths TT1 and TT2 may be larger than the widths L1 and L2 of the semiconductor laser elements, and are, for example, in a range from 0.10 mm to 0.50 mm, preferably in a range from 0.20 mm to 0.40 mm. The lengths of the first power supply terminal 12 and the second power supply terminal 22 in the Y direction are +50%, preferably +30%, more preferably +20% of the lengths of the semiconductor laser elements.

The first power supply terminal 12 and the second power supply terminal 22 can each be formed using, for example, a layer of a conductive material. The layer of the conductive material may be disposed on the base portion 9, or may be disposed on a heat dissipation member, such as the above-described submount. The layer of the conductive material can have a single-layer structure or a layered structure containing, for example, a metal, such as Au, Pt, Pd, Rh, Ru, Ni, W, Mo, Cr, Ti, Al, Cu, Ta, or Si, or an alloy thereof. Specifically, a layered structure, such as Ti/Rh/Au, Ti/Pt/Au, W/Pt/Au, Rh/Pt/Au, Ni/Pt/Au, Ti/Ru/Ti, Ti/Al-Si/Ta/Ru, Rh/Ni/Au, or Ru/Ni/Au can be employed.

The first power supply terminal 12 is connected to the first semiconductor laser element 11 via the first conductive members 14. The second power supply terminal 22 is connected to the second semiconductor laser element 21 via the second conductive members 24. A plurality of the first conductive members 14 are disposed for each of the first power supply terminals 12, and the plurality of first conductive members 14 are disposed for each of the first semiconductor laser elements 11. A plurality of the second conductive members 24 are disposed for each of the second power supply terminals 22, and the plurality of second conductive members 24 are disposed for each of the second semiconductor laser elements 21. For example, two to ten first conductive members 14 and two to ten second conductive members 24 can be disposed for each of the power supply terminals or each of the semiconductor laser elements, and the number of each of the first conductive members 14 and the second conductive members 24 is preferably in a range from three to six. The plurality of conductive members disposed for one power supply terminal or one semiconductor laser element are preferably arranged in the longitudinal direction (the Y direction in the drawing) when viewed in a top view. With such a configuration, even when the output of a light-emitting device increases, the current is distributed to the conductive members, and even when the length of each of the conductive members is shortened, disconnection is less likely to occur.

The first conductive members 14 and the second conductive members 24, for example, have linear shapes, and are preferably metal wires. As the metal, for example, gold, aluminum, silver, copper, an alloy thereof, or the like can be used.

As illustrated in FIG. 1A, the first power supply terminals 12 and the first conductive members 14 can individually connect the plurality of first semiconductor laser elements 11 to an external power supply via the external connection electrodes 4. When the plurality of second semiconductor laser elements 21 are present, the second power supply terminals 22 and the second conductive members 24 can individually connect the plurality of second semiconductor laser elements 21 to the external power supply via the external connection electrodes 4.

The plurality of first semiconductor laser elements 11 and one or more second semiconductor laser elements 21 are preferably individually connected to the external power supply via the external connection electrodes 4.

As illustrated in FIGS. 1A and 2, in a case in which the light source device includes a protecting element 3, such as a Zener diode, for each of the semiconductor laser elements, each of the protecting elements 3 is also connected to the power supply terminal. In this case, the semiconductor laser elements and the protecting elements 3 are preferably individually connected to the external power supply with the power supply terminals. With such a connection, when a plurality of sets of the semiconductor laser element and the protecting element are arrayed, they can be connected in parallel or in series.

Third Power Supply Terminal 32 and Fourth Power Supply Terminal 42

The third power supply terminal 32 is a member electrically connected to a corresponding one of the first semiconductor laser elements 11 to apply a driving voltage, and is a member corresponding to a corresponding one of the first power supply terminals 12. The fourth power supply terminal 42 is a member electrically connected to a corresponding one of the second semiconductor laser elements 21 to apply a driving voltage and is a member corresponding to a corresponding one of the second power supply terminals 22. The third power supply terminal 32 is disposed for each of the first semiconductor laser elements 11. The fourth power supply terminal 42 is disposed for each of the second semiconductor laser elements 21. The third power supply terminal 32 and the fourth power supply terminal 42 are electrically connected to the corresponding external connection electrodes 4 via the conductive circuit embedded in the wall portion 8 and/or the base portion 9.

The third power supply terminal 32 and the fourth power supply terminal 42 may be provided between the inner lateral surface of the wall portion 8 and the end portions of the semiconductor laser elements closer to the inner lateral surface of the wall portion 8 in a top view. Further, as illustrated in the drawings, steps can be provided on the wall portion 8, and the third power supply terminals 32 and the fourth power supply terminals 42 can be provided on the steps. The third power supply terminals 32 and the fourth power supply terminals 42 are disposed on the side opposite to the first reflecting members and the second reflecting members with respect to the corresponding semiconductor laser elements. There may be a case in which, rather than providing the first power supply terminal 12 and the third power supply terminal 32 or the second power supply terminal 22 and the fourth power supply terminal 42 between two adjacent lasers, providing only one of them between the two lasers and the other at a different position allows downsizing of the size of the package.

The third power supply terminal 32 and the first semiconductor laser element 11 are electrically connected via third conductive members 34 made of metal wires or the like. The fourth power supply terminal 42 and the second semiconductor laser element 21 are electrically connected via fourth conductive members 44 made of metal wires or the like. In this case, one end of each of the third conductive members 34 is bonded to a corresponding one of the third power supply terminals 32, and one end of each of the fourth conductive members 44 is bonded to a corresponding one of the fourth power supply terminals 42. The other end of each of the third conductive members 34 is directly bonded to a corresponding one of the first semiconductor laser elements 11 or bonded to the submount on which a corresponding one of the first semiconductor laser elements 11 is disposed. Alternatively, the other end of each of the fourth conductive members 44 is directly bonded to a corresponding one of the second semiconductor laser elements 21 or bonded to the submount on which a corresponding one of the second semiconductor laser elements 21 is disposed. In the case of being bonded to the submounts, the third power supply terminal 32 and the fourth power supply terminal 42 are electrically connected to the corresponding semiconductor laser elements via conductive members and metal films provided on the surfaces of the submounts.

A plurality of conductive members are provided for one third power supply terminal 32 or one fourth power supply terminal 42. One conductive member may be provided for one third power supply terminal 32 or one fourth power supply terminal 42. For the first power supply terminal 12 and the third power supply terminal 32 regarding the first semiconductor laser element 11, the number of the first conductive members 14 provided for the first power supply terminal 12 is larger than the number of the third conductive members 34 provided for the third power supply terminal 32. For the second power supply terminal 22 and the fourth power supply terminal 42 regarding the second semiconductor laser element 21, the number of the second conductive members 24 provided for the second power supply terminal 22 is larger than the number of the fourth conductive members 44 provided for the fourth power supply terminal 42. When a plurality of conductive members are provided for one third power supply terminal 32 or one fourth power supply terminal 42, the conductive members are preferably arrayed in the X direction. In this way, the power supply terminals are provided effectively utilizing the spaces and the number of conductive members provided for the power supply terminals is adjusted in accordance with the shapes of the power supply terminals, whereby the size of the package can be downsized.

Furthermore, the sizes of the third power supply terminal 32 and the fourth power supply terminal 42 in the X direction are preferably shorter than the lengths of the first semiconductor laser element 11 and the second semiconductor laser element 21 in the Y direction. The sizes of the third power supply terminal 32 and the fourth power supply terminal 42 in the X direction are preferably shorter than the lengths of the first power supply terminal 12 and the second power supply terminal 22 in the Y direction. The sizes of the third power supply terminal 32 and the fourth power supply terminal 42 in the X direction are preferably shorter than the lengths of the submounts in the X direction. With such sizes, the distances between the third power supply terminal 32 and the first semiconductor laser element 11 and between the fourth power supply terminal 42 and the second semiconductor laser element 21 can be reduced, and the driving voltage can be reduced. The lengths of the third power supply terminal 32 and the fourth power supply terminal 42 in the X direction may be longer than the lengths of the first semiconductor laser element 11, the second semiconductor laser element 21, the first power supply terminal 12, and the second power supply terminal 22 in the Y direction. The distance in the Y direction between the two first conductive members 14 disposed at both ends in the Y direction among the plurality of first conductive members 14 provided for the first power supply terminal 12 is longer than the length of the first semiconductor laser element 11 in the X direction. The distance in the Y direction between the two first conductive members 14 disposed at both ends in the Y direction among the plurality of first conductive members 14 provided for the first power supply terminal 12 is longer than the length of the submount on which the first semiconductor laser element 11 is disposed in the X direction. The distance in the Y direction between the two first conductive members 14 disposed at both ends in the Y direction among the plurality of first conductive members 14 provided for the first power supply terminal 12 is longer than the length in the X direction of the first reflecting member 13 that reflects the light from the first semiconductor laser element 11. By providing the first power supply terminal 12 not in the X direction but in the Y direction between the adjacent first semiconductor laser elements 11, the size of the package can be downsized. The third power supply terminal 32 and the fourth power supply terminal 42 may be formed of, for example, the same material as the first power supply terminal 12 and the second power supply terminal 22.

First Reflecting Member 13 and Second Reflecting Member 23

The first reflecting members 13 and the second reflecting members 23 are arrayed on the base portion 9.

The plurality of first reflecting members 13 are arrayed along the array direction (X direction), and are spaced apart from the plurality of first semiconductor laser elements 11 in the first optical axis direction Y1. One or more second reflecting members 23 are spaced apart from one or more second semiconductor laser elements 21 in the second optical axis direction Y2. When a plurality of the second reflecting members 23 are disposed, the plurality of second reflecting members 23 are arrayed along the array direction. The distance between the first reflecting member 13 and the first semiconductor laser element 11 and the distance between the second reflecting member 23 and the second semiconductor laser element 21 can be set arbitrarily.

The plurality of first reflecting members 13 and one or more second reflecting members 23 can be alternately disposed along the array direction. The first reflecting members 13 and the second reflecting members 23 are preferably disposed so as to be partially or entirely opposed to each other in the X direction.

For example, as illustrated in FIG. 1C, the first reflecting member 13 is a first mirror member having a first reflecting surface 13a. The first reflecting surface 13a receives laser light emitted from the first semiconductor laser element 11 and reflects the laser light in a light emission direction (Z direction) orthogonal to the array direction (X direction) and the first optical axis direction (Y1 direction).

The second reflecting member 23 is a second mirror member having a second reflecting surface 23a. The second reflecting surface 23a receives laser light emitted from the second semiconductor laser element 21 and reflects the laser light in the light emission direction, that is, the light emission direction (Z direction) orthogonal to the second optical axis direction (Y2 direction).

The reflecting surface is inclined with respect to a surface on which the first semiconductor laser element 11 and the second semiconductor laser element 21 are disposed in the surfaces of the base portion 9. The reflecting surface is disposed on the base portion 9 so as to be an inclined surface having an inclination angle in a range from 5 degrees to 85 degrees, for example, 45 degrees, with respect to the surface of the base portion 9. The reflecting surface may have either a flat plane shape or a curved shape. In the case of a curved shape, a portion which is perpendicular or parallel when viewed from the lower surface may be locally included. In particular, the reflecting surface preferably has a flat plane shape.

The reflecting members can be formed using glass, metal, or the like. Specifically, the reflecting member can be formed using quartz, glass such as BK7 (borosilicate glass), a metal such as aluminum, or a material containing Si as a main material. The reflecting surface can be formed using, for example, a metal such as Ag or Al, or a dielectric multilayer film of Ta₂O₅/SiO₂, TiO₂/SiO₂, Nb₂O₅/SiO₂, or the like. The reflecting surface achieves a light reflectivity of, for example, 99% or more for the peak wavelength of the reflected laser light, and the light reflectivity therefor may be 95% or more, or 90% or more.

Intersection points (IP1) between the plurality of first reflecting surfaces 13a and the optical axes of the first semiconductor laser elements 11 and intersection points (IP2) between one or more second reflecting surfaces and the optical axes of the second semiconductor laser elements 21 are preferably disposed to constitute respective virtual straight lines (VSL1, VSL2) in a top view, as illustrated in FIG. 1E. In other words, as will be described later, the first reflecting member and the second reflecting member are preferably disposed such that light reflection points on the reflecting surfaces thereof, that is, points at which light from the first semiconductor laser element and light from the second semiconductor laser element are reflected are disposed on respective straight lines in a top view. In particular, the point (IP1) at which the light from the first semiconductor laser element is reflected and the point (IP2) at which the light from the second semiconductor laser element is reflected are preferably disposed on the same straight line (VSL), as illustrated in FIG. 1D. With such a structure, variation in irradiation when light-emitting portions are turned on and off is reduced and a uniform pattern can be obtained.

A virtual flat plane passing through the exit end surface of the first semiconductor laser element 11 passes through the second reflecting member. A virtual flat plane passing through the exit end surface of the second semiconductor laser element 21 passes through the first reflecting member. Furthermore, in a top view, the length in the Y direction of the first reflecting surface 13a can be set in a range from 85% to 95% of the length in the Y direction of the first reflecting member 13, and in a top view, the length in the Y direction of the second reflecting surface 23a can be set in a range from 85% to 95% of the length in the Y direction of the second reflecting member 23.

Package

As described above, the base portion 9 constitutes a part of the package. As illustrated in FIG. 1C, an example of the package includes a housing-shaped package that accommodates the semiconductor laser elements in a recessed portion. In this case, the package includes the base portion 9 and the wall portion 8 surrounding the base portion 9, and a recessed portion 7 is formed by the base portion 9 and the inner lateral surface of the wall portion 8. The wall portion 8 has an inner lateral surface, an outer lateral surface opposite to the inner lateral surface, and an upper surface in contact with the inner lateral surface and the outer lateral surface. The inner lateral surface of the wall portion 8 may further have a step. The wall portion 8 and the base portion 9 may be integrally formed of the same material, or may be formed of different materials. As illustrated in FIGS. 1A and 1C, the wall portion 8 may be provided with metal portions or the like serving as external connection electrodes 4 on its surface or inside thereof, as wiring lines or the like for electrical connection. Examples of the material of the metal portion include the same materials as those of the metal portion of the base portion 9. When the base portion 9 and the wall portion 8 constitute the package, the package may have a lid member 6. In FIG. 1C, the lid member 6 is constituted by a heat dissipation member 6a and a wavelength conversion member 5. In FIG. 1C, the wavelength conversion member 5 is constituted by a surrounding portion 5a and a wavelength conversion portion 5b. The lid member 6 is bonded to the wall portion 8 under a predetermined atmosphere, and a hermetically sealed space can be formed by the base portion 9, the wall portion 8, and the lid member 6. By disposing the semiconductor laser elements and the like in the hermetically sealed space, it is possible to inhibit quality degradation due to dust collection. For hermetic sealing, the lid member 6 is bonded to the wall portion 8 with, for example, an adhesive, a metal bonding material, or the like. Examples of the metal bonding material include a brazing metal such as AuSn, solder, and the like. In FIG. 1C, the heat dissipation member 6a is bonded to the wall portion 8. The heat dissipation member 6a has a lower surface and an upper surface. The heat dissipation member 6a preferably has, for example, a flat plate shape, and preferably has an outer shape equivalent to an outer shape of the base portion 9 or a smaller shape than the outer shape of the base portion 9 in a top view.

The heat dissipation member 6a preferably has light transmissivity for transmitting light. Here, the term “light transmissivity” means that the transmittance for lights emitted from the semiconductor laser elements accommodated in the package is, for example, 50% or more, and is preferably 60% or more, 70% or more, or 80% or more. The heat dissipation member 6a may entirely have light transmissivity, or may partially have light transmissivity only in a region. The heat dissipation member 6a can be made of a ceramic, sapphire, glass, or the like. Among them, the heat dissipation member 6a is preferably made of a light-transmissive member such as sapphire or glass. Examples of the metal include ones similar to those of the base portion 9. Sapphire is a material having light transmissivity, a relatively high refractive index, and a relatively high strength. As illustrated in FIG. 1C, the surrounding portion 5a and the wavelength conversion portion 5b may be disposed in contact with the heat dissipation member 6a. The wavelength conversion portion 5b can contain a phosphor known in the field. The wavelength conversion member 5 has a plurality of light exit surfaces separated from each other on the upper surface, and each of the light exit surfaces is formed by the wavelength conversion portion 5b. The number of light exit surfaces is preferably the same as the sum of the number of first semiconductor laser elements 11 and the number of second semiconductor laser elements 21 so that the respective light exit surfaces correspond to the first semiconductor laser elements 11 and the second semiconductor laser elements 21. In other words, a plurality of the wavelength conversion portions 5b are preferably disposed separated from each other, for example, above the first reflecting members 13 and the second reflecting members 23 so as to correspond to the first semiconductor laser elements 11 and the second semiconductor laser elements 21. The wavelength conversion portion 5b may be integrally formed. The distance between the centers of the adjacent light exit surfaces may be substantially equal to the distance between the center of the first reflecting member 13 and the center of the second reflecting member 23 that are adjacent to each other. The size and the shape of the wavelength conversion portion 5b can be set arbitrarily. For example, the wavelength conversion portion 5b has its periphery surrounded by the surrounding portion 5a and has a flat plate shape, and the wavelength conversion portion 5b can be disposed on and in contact with the heat dissipation member 6a. The surrounding portion 5a may be made of the same material as that of the heat dissipation member 6a, or may be made of a different material. For example, the surrounding portion 5a can be made of a ceramic.

Optical Member

The optical member may be disposed on the package, that is, on the lid member 6. The optical member is a member for arbitrary light distribution, such as light collection. The optical member has an upper surface, a lower surface, and a lateral surface, and may have a lens surface. The lens surface is preferably formed on either the upper surface or the lower surface. For example, the optical member has, as a whole, a shape in which a lens surface having a dome shape or the like is disposed on one surface of a flat plate shape. The lens surface may be formed of one dome-shaped lens, or may have any of a shape in which a plurality of lens surfaces are connected to each other, a shape in which a plurality of lenses are arrayed in parallel, and the like. In this case, the plurality of lens surfaces are preferably respectively disposed above the plurality of wavelength conversion portions described above. The optical member may be formed by integrating a flat plate-shaped portion and a lens, or may be formed by bonding separate members together. The optical member may have, for example, any of various outer shapes in a top view, similarly to the base portion 9, but preferably has a rectangular shape. The optical member has light transmissivity, and the lens surface and the other portions also preferably have light transmissivity. The optical member can be formed using, for example, glass such as BK7.

Protecting Element 3

The protecting element 3 is an element that prevents the semiconductor laser element from being broken down by an excessive current flowing therethrough. An example of the protecting element 3 is a Zener diode. The Zener diode may be formed of Si.

As illustrated in FIGS. 1A and 2, the protecting element 3 can be disposed for each of the semiconductor laser elements. In this case, the protecting element 3 is preferably disposed in a region except the virtual straight lines including the optical axes of laser light emitted from the semiconductor laser elements.

The light-emitting device according to the embodiments can be used for projectors, in-vehicle headlights, head-mounted displays, lighting, displays and the like.

What is claimed is:

1. A light source device comprising:
a base portion;
a plurality of first semiconductor laser elements arrayed on the base portion along an array direction, each of the first semiconductor laser elements being configured to emit laser light in a first optical axis direction perpendicular to the array direction;
one or more first power supply terminals each disposed respectively in a region interposed between adjacent ones of the first semiconductor laser elements and electrically connected to a corresponding one of the first semiconductor laser elements;
a plurality of first reflecting members arrayed on the base portion along the array direction, the first reflecting members being spaced apart from the first semiconductor laser elements in the first optical axis direction;
one or more second semiconductor laser elements each configured to emit laser light in a second optical axis direction perpendicular to the array direction and opposite to the first optical axis direction;
one or more second power supply terminals each electrically connected to a corresponding one of the one or more second semiconductor laser elements; and
one or more second reflecting members spaced apart from the one or more second semiconductor laser elements in the second optical axis direction, wherein
at least one of the one or more second reflecting members is disposed in a region interposed between adjacent ones of the first reflecting members in the array direction.

2. The light source device according to claim 1, wherein
the one or more second semiconductor laser elements are constituted by a plurality of second semiconductor laser elements arrayed on the base portion along the array direction, and each of the second semiconductor laser elements is configured to emit light in the second optical axis direction,
each of the one or more second power supply terminals is disposed in a region interposed between adjacent ones of the second semiconductor laser elements,
the one or more second reflecting members are constituted by a plurality of second reflecting members arrayed on the base portion along the array direction, and the second reflecting members are spaced apart from the second semiconductor laser elements in the second optical axis direction, and
at least one of the first reflecting members is disposed in a region interposed between adjacent ones of the second reflecting members.

3. The light source device according to claim 2, further comprising:
a first conductive member connecting one of the first power supply terminals and a corresponding one of the first semiconductor laser elements; and
a second conductive member connecting one of the second power supply terminals and a corresponding one of the second semiconductor laser elements.

4. The light source device according to claim 2, further comprising:
a plurality of first conductive members connecting a respective one of the first power supply terminals and a respective one of the first semiconductor laser elements; and
a plurality of second conductive members connecting a respective one of the second power supply terminals and a respective one of the second semiconductor laser elements.

5. The light source device according to claim 2, wherein
each of the first reflecting members is a first mirror member having a first reflecting surface configured to receive laser light emitted from a corresponding one of the first semiconductor laser elements and reflect the laser light in a light emission direction orthogonal to the array direction and the first optical axis direction, and
each of the second reflecting members is a second mirror member having a second reflecting surface configured to receive laser light emitted from a corresponding one of the second semiconductor laser elements and reflect the laser light in the light emission direction.

6. The light source device according to claim 2, further comprising
a plurality of wavelength conversion portions each corresponding to a corresponding one of the first semiconductor laser elements and the second semiconductor laser elements.

7. The light source device according to claim 6, further comprising
a lid member disposed on the base portion, wherein
the wavelength conversion portions are separated apart from each other and disposed on the lid member.

8. The light source device according to claim 7, wherein
the lid member contains at least one of glass, sapphire, metal, or ceramic.

9. The light source device according to claim 5, wherein
the first semiconductor laser elements and the first reflecting members are arranged so that all intersection points between an optical axis of a respective one of the first semiconductor laser elements and the first reflecting surface of a respective one of the first reflecting members are arranged on a first virtual straight line, and
the second semiconductor laser elements and the second reflecting members are arranged so that all intersection points between an optical axis of a respective one of the second semiconductor laser elements and the second reflecting surface of a respective one of the first reflecting members are arranged on a second virtual straight line.

10. The light source device according to claim 9, wherein
the first virtual straight line coincides the second virtual straight line.

11. The light source device according to claim 1, wherein
all of the first semiconductor laser elements and the one or more second semiconductor laser elements exhibit wavelength peaks in blue.

12. The light source device according to claim 2, wherein
the first power supply terminals are arranged on an opposite side of the second semiconductor laser elements with respect to the second reflecting members, and a distance between one of the first power supply terminals and a corresponding one of the second reflecting members is shorter than a length of the one of the first power supply terminals in the first optical axis direction; and
the second power supply terminals are arranged on an opposite side of the first semiconductor laser elements with respect to the first reflecting members, and a distance between one of the second power supply terminals and a corresponding one of the first reflecting members is shorter than a length of the one of the second power supply terminals in the second optical axis direction.

13. The light source device according to claim 2, further comprising
a plurality of submounts disposed on the base portion, wherein
the first semiconductor laser elements and the second semiconductor laser elements are disposed on the base portion via the corresponding submounts, respectively, and
a width of each of the submounts in the array direction is larger than a width of each of the first power supply terminals in the array direction and a width of each of the second power supply terminals in the array direction.

14. The light source device according to claim 2, wherein
each of the first semiconductor laser elements and the second semiconductor laser elements is configured to be individually connected to an external power supply.
